(19) United States
(12) Patent Application Publication
(10) Pub. No.: US 2026/0262244 A1
(43) Pub. Date: Sep. 3, 2026

(54) SEMICONDUCTOR DEVICE AND MEASUREMENT DEVICE

(71) Applicants: Ryota SUTO, Kyoto (JP); Hiroaki KAWAMURA, Hyogo (JP)

(72) Inventors: Ryota SUTO, Kyoto (JP); Hiroaki KAWAMURA, Hyogo (JP)

(21) Appl. No.: 19/155,569

(22) PCT Filed: Feb. 13, 2024
(86) PCT No.: PCT/JP2024/004855

§ 371 Date: Aug. 12, 2025

(30) Foreign Application Priority Data
Feb. 13, 2023 (JP) 2023-020030

(51) Int. Cl. H10D 30/47; G01N 27/414; H10D 62/17; H10D 62/80; H10D 64/23; H10D 64/27

(52) U.S. Cl. CPC H10D 30/481; G01N 27/4145; H10D 62/882; H10D 62/292; H10D 64/251; H10D 64/514

(57) ABSTRACT

A semiconductor device includes a gate electrode, an insulating portion, a channel material, a source electrode, and a drain electrode. The insulating portion is on one surface of the gate electrode. The channel material is on a surface of the insulating portion opposite to the gate electrode. The channel material includes an atomic-layered material including graphene. The source electrode is connected to one end of the channel material. The drain electrode is connected to one end of the channel material opposite to the source electrode. At least one of the source electrode and the drain electrode comprises a metal material having a lower ionization tendency than hydrogen. At least one of the source electrode and the drain electrode is connected to the insulating portion via a metal material having a higher ionization tendency than hydrogen.

### TECHNICAL FIELD

The present invention relates to a semiconductor device and a measurement device.

### BACKGROUND ART

Conventionally, research and development on various sensors are being conducted, and sensors are widely spread in industrial to medical fields and even in general households, which indicates that the sensors are indispensable in modern society. The sensors are classified by, for example, a measurement target, a signal conversion function, a constituent material, or the like. The signal conversion function is roughly divided into a physical sensor, a chemical sensor, and a biosensor.

Among the sensors as described above, the biosensor is a measurement device that mimics or directly uses an excellent molecular recognition ability of a living body, and therefore, is attracting attention because it is expected that the biosensor is widely applicable.

For example, a biosensor that uses a semiconductor device, such as a field-effect transistor (FET), is recently attracting attention because this kind of biosensor is able to perform sensing by using the fact that the amount of charge of a channel changes in accordance with concentration of a target substance, and therefore is able to perform sensing easily. To enable sensing of a small quantity, there are already known technologies that enable sensing with high sensitivity by using, as a channel material, an atomic layer material, such as graphene, or a fine fiber material, such as a carbon nanotube (CNT), that has high field-effect mobility and a large surface area.

A Graphene Field Effect Transistor (GFET) that uses graphene as a channel is expected to be applied to various uses because of unique physical properties of the graphene. The graphene has ultra-high mobility that is more than hundred times higher than silicon (Si) and has a large surface area ratio with respect to a channel volume because the graphene has a two-dimensional shape, and therefore, is attracting attention as a high sensitive sensor and is particularly expected to be applied to biosensing for biomolecule or the like because the graphene is composed only of carbon and has good compatibility with the biomolecule.

Patent Literature 1 discloses a graphene transistor that has an uneven surface portion in a region just below an ohmic electrode to reduce contact resistance between graphene and each of a source electrode and a drain electrode, and discloses a configuration of the graphene transistor in which a graphene film is formed in a region just above the unevenness portion and the ohmic electrode is disposed on the graphene film to increase a contact area between the graphene film and the ohmic electrode to thereby reduce the contact resistance.

Patent Literature 2 discloses a graphene transistor in which graphene just below a source electrode and a drain electrode includes carbon atom vacancies to prevent an increase in contact resistance between the graphene and a metal that is connected to the graphene, and discloses a configuration in which the contact resistance is reduced by increasing the number of connections between the metal electrode and carbon atoms that are present at an edge of the graphene.

### SUMMARY OF INVENTION

### Technical Problem

However, in the configuration as described above, it is possible to reduce the contact resistance between the graphene (one example of a channel material) and the metal electrode (the source electrode and the drain electrode), but adhesiveness between the metal electrode and a substrate, which is extremely important in terms of reliability at the time of commercialization, may be reduced. In particular, Pd, Pt, Au, or the like which are reported to have low contact resistance with graphene (see Non Patent Literatures 1 and 2) have poor adhesion to silicon oxide film (an example of an insulating film), which is commonly used base substrate, and therefore are easily peeled off.

The present invention has been conceived in view of the foregoing situation, and an object of the present invention is to provide a semiconductor device and a measurement device capable of reducing contact resistance and improving adhesiveness by separately providing a contact metal that comes into contact with graphene and a wiring metal that is disposed on a base substrate.

### Solution to Problem

In order to solve the above problem and achieve the object, a semiconductor device includes a gate electrode, an insulating portion, a channel material, a source electrode, and a drain electrode. The insulating portion is on one surface of the gate electrode. The channel material is on a surface of the insulating portion opposite to the gate electrode. The channel material includes an atomic-layered material including graphene. The source electrode is connected to one end of the channel material. The drain electrode is connected to one end of the channel material opposite to the source electrode. At least one of the source electrode and the drain electrode comprises a metal material having a lower ionization tendency than hydrogen. At least one of the source electrode and the drain electrode is connected to the insulating portion via a metal material having a higher ionization tendency than hydrogen.

### Advantageous Effects of Invention

According to an aspect of the present invention, a contact metal that comes into contact with graphene and a wiring metal that is disposed on a base substrate are separated, so that it is possible to reduce contact resistance and improve adhesiveness.

### BRIEF DESCRIPTION OF DRAWINGS

FIG. 1 is a diagram illustrating an example of a cross-sectional structure of a conventional graphene transistor.

FIG. 2A is a diagram illustrating an example of a configuration of a graphene transistor according to a first embodiment.

FIG. 2B is a diagram illustrating an example of a configuration of a graphene transistor according to a modification 1-1.

FIG. 2C is a diagram illustrating an example of a configuration of a graphene transistor according to a modification 1-2.

FIG. 2D is a diagram illustrating an example of a configuration of a graphene transistor according to a modification 1-3.

FIG. 2E is a diagram illustrating an example of a configuration of a graphene transistor according to a modification 1-4.

FIG. 2F is a diagram illustrating an example of a configuration of a graphene transistor according to a modification 1-5.

FIG. 2G is a diagram illustrating an example of a configuration of a graphene transistor according to a modification 1-6.

FIG. 2H is a diagram illustrating an example of a configuration of a graphene transistor according to a modification 1-7.

FIG. 3A is a diagram illustrating an example of a configuration of a graphene transistor according to a second embodiment.

FIG. 3B is a diagram illustrating an example of a configuration of a graphene transistor according to a modification 2-1.

FIG. 3C is a diagram illustrating an example of a configuration of a graphene transistor according to a modification 2-2.

FIG. 4A is a diagram illustrating an example of a configuration of a graphene transistor according to a third embodiment.

FIG. 4B is a diagram illustrating an example of a configuration of a graphene transistor according to a modification 3-1.

FIG. 4C is a diagram illustrating an example of a configuration of a graphene transistor according to a modification 3-2.

FIG. 5A is a diagram illustrating an example of a configuration of a graphene transistor according to a fourth embodiment.

FIG. 5B is a diagram illustrating an example of a configuration of a graphene transistor according to a modification 4-1.

FIG. 5C is a diagram illustrating an example of a configuration of a graphene transistor according to a modification 4-2.

FIG. 6A is a diagram illustrating an example of a configuration of a graphene transistor according to a fifth embodiment.

FIG. 6B is a diagram illustrating an example of a configuration of a graphene transistor according to a modification 5-1.

FIG. 6C is a diagram illustrating an example of a configuration of a graphene transistor according to a modification 5-2.

FIG. 6D is a diagram illustrating an example of a configuration of a graphene transistor according to a modification 5-3.

FIG. 7A is a diagram illustrating an example of a configuration of a graphene transistor according to a sixth embodiment.

FIG. 7B is a diagram illustrating an example of a configuration of a graphene transistor according to a modification 6-1.

FIG. 7C is a diagram illustrating an example of a configuration of a graphene transistor according to a modification 6-2.

FIG. 7D is a diagram illustrating an example of a configuration of a graphene transistor according to a modification 6-3.

FIG. 8A is a diagram illustrating an example of a configuration of a graphene transistor according to a seventh embodiment.

FIG. 8B is a diagram illustrating an example of a configuration of a graphene transistor according to a modification 7-1.

FIG. 8C is a diagram illustrating an example of a configuration of a graphene transistor according to a modification 7-2.

FIG. 8D is a diagram illustrating an example of a configuration of a graphene transistor according to a modification 7-3.

FIG. 9A is a diagram illustrating an example of a configuration of a graphene transistor according to an eight embodiment.

FIG. 9B is a diagram illustrating an example of a configuration of a graphene transistor according to a modification 8-1.

FIG. 10A illustrates a result of a scratch test on various kinds of metals on a silicon thermal oxide film (SiO₂).

FIG. 10B illustrates a result obtained by measuring contact resistance between graphene and various kinds of metals by a Transfer Line Method (TLM).

FIG. 10C is a diagram illustrating a representative example of electrical property in a case where a source electrode and a drain electrode in the conventional graphene transistor illustrated in FIG. 1 are made of various kinds of metals.

FIG. 10D is a diagram illustrating average values of Hall field-effect mobility, electron field-effect mobility, ON/OFF (maximum value of a drain electrical current/minimum value of the drain electrical current) of six elements in the conventional graphene transistor illustrated in FIG. 1.

FIG. 11 is a block diagram illustrating an embodiment of a measurement device.

### DESCRIPTION OF EMBODIMENTS

Embodiments of a semiconductor device will be described in detail below with reference to the accompanying drawings.

### First Embodiment

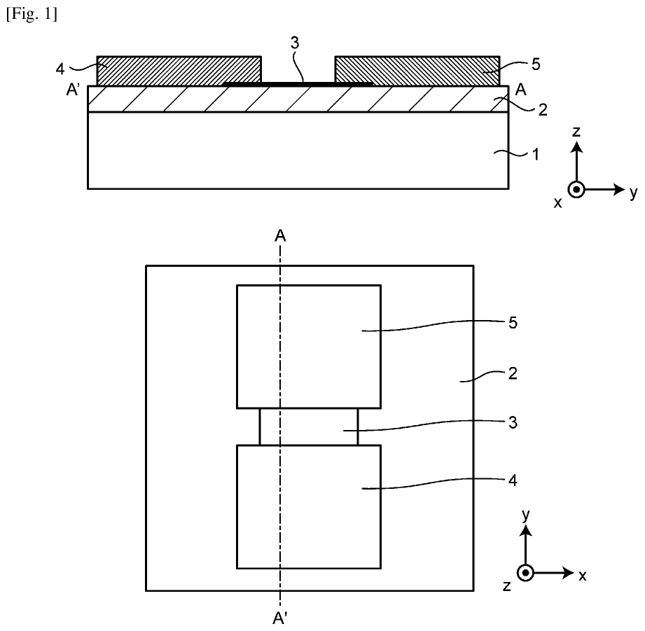

FIG. 1 is a diagram illustrating an example of a cross-sectional structure of a conventional graphene transistor. The conventional graphene transistor includes, as illustrated in FIG. 1, a substrate 1, an insulating film 2, a channel 3, a source electrode 4, and a drain electrode 5.

The substrate 1 may be a conductive substrate, such as a heavily doped silicon substrate, for example. In the conventional graphene transistor illustrated in FIG. 1, the substrate 1 functions as an example of a gate electrode. The insulating film 2 is disposed on the substrate 1. In the conventional graphene transistor illustrated in FIG. 1, the insulating film 2 functions as an example of an insulating portion that is disposed on one surface of the substrate 1. The channel 3 is one example of a channel material that is disposed on one surface of the insulating film 2 opposite to the substrate and that includes an atomic-layered material including graphene.

The source electrode 4 is one example of a source electrode that is connected to one end of the channel 3. The drain electrode 5 is one example of a drain electrode that is connected to one end of the channel 3 opposite to the source electrode 4. The source electrode 4 and the drain electrode 5 cause the channel 3 to induce a carrier by applying voltage V_{gs} to the substrate 1 while applying voltage V_{ds}. Accordingly, an electrical current I_{ds} flows between the source electrode 4 and the drain electrode 5. The graphene transistor is able to modulate a magnitude of the electrical current I_{ds} by a magnitude of the voltage V_{gs}, and operates as a field-effect transistor (back-gate transistor).

As a performance indicator of the transistor, a field-effect mobility μ_{FE} is used, and μ_{FE} is represented by Expression (1) below.

$${μ}_{FE} = \frac{L \times {g}_{m}}{W \times {C}_{ox} \times {V}_{ds}} \qquad ( 1 )$$

Here, L represents a channel length, W represents a channel width, V_{ds} represents voltage between a source and a drain, gₘ represents a mutual conductance that is represented by Expression (2) below, and Cₒₓ represents a gate capacity that is represented by Expression (3) below.

$${g}_{m} = \frac{Δ {I}_{ds}}{Δ {V}_{g}} \qquad ( 2 )$$

$${C}_{ox} = \frac{{ε}_{0} \times ε}{d} \qquad ( 3 )$$

ε₀ represents permittivity in vacuum (8.85×10⁻¹⁴ F/cm), E represents relative permittivity of a gate insulating film, and d represents a film thickness of the gate insulating film.

According to Expression (1), the performance of the transistor increases with an increase in the mutual conductance gₘ that is represented by Expression (2). In other words, according to Expression (2), the performance of the transistor increases with an increase in a change rate ΔI_{d} of the drain electrical current. To realize this situation, it should obtain a larger drain electrical current I_{d}, at the same drain voltage V_{ds} by decreasing contact resistance R_{c} between the channel 3 and each of the source electrode 4 and the drain electrode 5.

With regard to the contact resistance R_{c} between the channel 3 and the source electrode 4 (or the drain electrode 5), in Non Patent Literature 1, it is described that the contact resistance R_{c} varies depending on a material, a manufacturing method, or a film thickness of the electrode. Further, Patent Literature 1 describes that an increase in the contact resistance R_{c} is prevented by devising a structure of a contact portion between the channel 3 and the source electrode 4 (or the drain electrode 5). Patent Literature 2 describes that it is possible to reduce the contact resistance R_{c} by devising a structure of the insulating film 2 just below the source electrode 4 or the drain electrode 5.

As described above, several methods for reducing the contact resistance R_{c} by devising materials, manufacturing methods, or film thicknesses of the source electrode 4 and the drain electrode 5 and a structure of the channel 3 or the insulating film 2 just below the source electrode 4 and the drain electrode 5 are known. However, when an actual device is manufactured, a contact region between the channel 3 and each of the source electrode 4 and the drain electrode 5 is only a small part of the substrate 1 or a chip, and most parts of the source electrode 4 and the drain electrode 5 come into contact with the insulating film 2. In Non Patent Literature 1, it is indicated that when the source electrode 4 and the drain electrode 5 (contact metals that come into contact with the channel 3) are made of Au or Pd, the contact resistance R_{c} is relatively low; however, in general, adhesiveness between the insulating film 2 (for example, silicon thermal oxide film SiO₂) and Au or Pd is low and reliability of the transistor may be degraded.

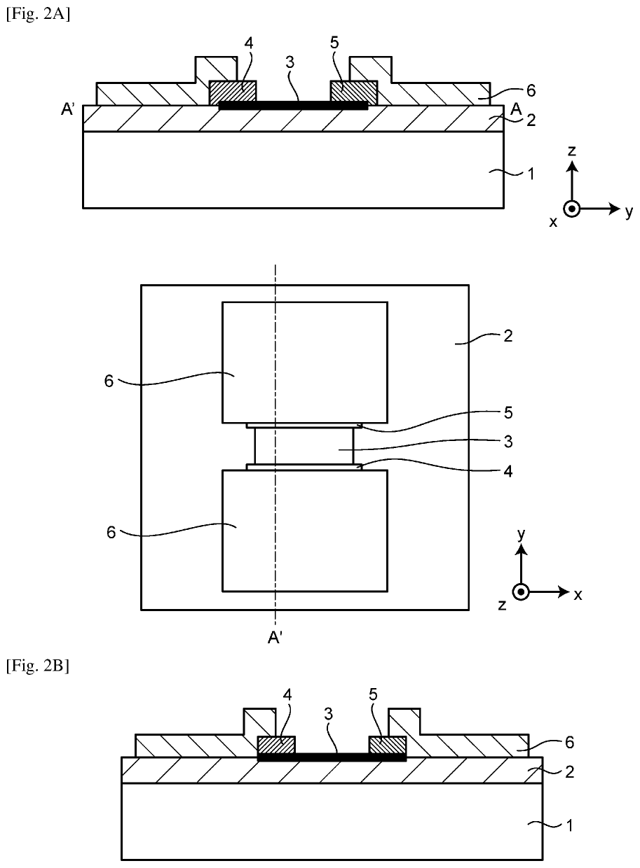

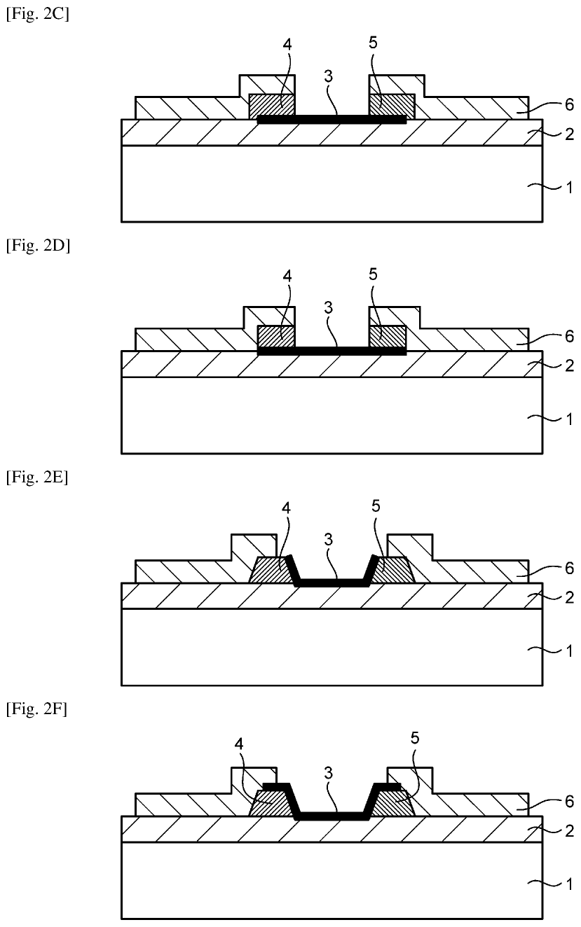

FIG. 2A is a diagram illustrating an example of a configuration of a graphene transistor according to a first embodiment. Specifically, FIG. 2A is a diagram illustrating a graphene transistor in which contact metals that come into contact with a graphene channel and a wiring metal on the insulating film are separately formed. The graphene transistor according to the present embodiment (one example of a semiconductor device) includes the substrate 1, the insulating film 2, the channel 3, the source electrode 4, the drain electrode 5, and a wiring metal 6. The graphene transistor according to the present embodiment may be used for a measurement device, such as biosensor.

The substrate 1 includes a gate electrode. The insulating film 2 is one example of an insulating portion that is disposed on one surface of the substrate 1. The channel 3 is one example of a channel material that is disposed on the insulating film 2 and that is made of an atomic-layered material including graphene.

The source electrode 4 is an electrode that is connected to the channel 3. Specifically, the source electrode 4 is one example of a source electrode that is connected to one end of the channel 3. The drain electrode 5 is an electrode that is connected to the channel 3. Specifically, the drain electrode 5 is one example of a drain electrode that is connected to one end of the channel 3 opposite to the source electrode 4. Here, at least one of the source electrode 4 and the drain electrode 5 is a metal material, such as a precious metal, that has a lower ionization tendency than hydrogen.

The wiring metal 6 is one example of a metal material that is connected to the source electrode 4 and the drain electrode 5, that is drawn on the insulating film 2, and that has a higher ionization tendency than hydrogen. In other words, the source electrode 4 and the drain electrode 5 are connected to the insulating film 2 via the wiring metal 6 that has a higher ionization tendency than hydrogen. In the present embodiment, both of the source electrode 4 and the drain electrode 5 are connected to the insulating film 2 via the wiring metal 6, but it is sufficient that at least one of the source electrode 4 and the drain electrode 5 is connected to the insulating film 2 via the wiring metal 6.

The metal that is connected to the insulating film 2 needs to be adhesive to the insulating film 2. Further, the metal that is connected to the channel 3 needs to have low contact resistance against the channel 3. In the graphene transistor illustrated in FIG. 2A, a part of each of the source electrode 4 and the drain electrode 5 is disposed on the insulating film 2; however, it is sufficient that a part of at least one of the source electrode 4 and the drain electrode 5 is disposed on the insulating film 2.

It is ideal that the source electrode 4 and the drain electrode 5 are disposed on only the channel 3 from the viewpoint of adhesiveness to the insulating film 2, and it is ideal that a contact area with the channel 3 is increased as much as possible from the viewpoint of contact resistance against the channel 3. However, by taking into account a margin, such as dimensional variation, in a photolithography (photoengraving) process, a part of each of the source electrode 4 and the drain electrode 5 is also disposed on the insulating film 2. Therefore, a width of each of the source electrode 4 and the drain electrode 5 on the insulating film 2 is no more than 10 micrometers (μm).

Similarly, the wiring metal 6 covers a part of a top surface of each of the source electrode 4 and the drain electrode 5, but it is ideal that the wiring metal 6 covers the entire top surface of each of the source electrode 4 and the drain electrode 5 from the view point of contact resistance between the wiring metal 6 and each of the source electrode 4 and the drain electrode 5. Furthermore, from the viewpoint of adhesiveness, the wiring metal 6 is able to physically press the source electrode 4 and the drain electrode 5 from above, and therefore, it is ideal that the wiring metal 6 covers the entire top surface of each of the source electrode 4 and the drain electrode 5. However, by taking into account a margin, such as dimensional variation, in a photolithography (photoengraving) process, the wiring metal 6 is configured so as not to cover the entire top surface of each of the source electrode 4 and the drain electrode 5. Therefore, a width of a region in which the wiring metal 6 is not present on the top surface of each of the source electrode 4 and the drain electrode 5 is no more than 10 μm.

The source electrode 4 and the drain electrode 5 that are connected to the channel 3 are formed by using a certain material, a certain method, and a certain film thickness that reduce the contact resistance against the channel 3. Further, the wiring metal 6 is formed by using a certain material, a certain method, and a certain film thickness that ensure adhesiveness to the insulating film 2.

For example, the substrate 1 may be formed of a heavily doped silicon substrate. Furthermore, the insulating film 2 may be formed of a thermal oxide film SiO₂. Moreover, the channel 3 may be made of graphene. Furthermore, the source electrode 4 and the drain electrode 5 may be made of palladium (Pd), contact resistance of which against graphene is considered to be low. Moreover, the wiring metal 6 may be formed of a laminated film (Ti/Au) of titanium (Ti) and gold (Au) that have high adhesiveness to the insulating film 2.

The source electrode 4 and the drain electrode 5 need not always be made of Pd, but may be made of a precious metal, such as platinum (Pt), gold (Au), or silver (Ag), which is conductive and for which contact resistance against graphene is considered to be low, or a laminated film of the precious metals. As a method of forming the source electrode 4 and the drain electrode 5, a vacuum deposition method, an electron-beam evaporation method, a sputtering method, or the like may be adopted, and it is desirable that a film thickness of each of the source electrode 4 and the drain electrode 5 is equal to or larger than 5 nanometers (nm), with which a continuous film rather than an island-shaped film is likely to be formed, and equal to or smaller than 200 nm to prevent disconnection of the wiring metal 6 at a stepped portion.

The wiring metal 6 need not always be made of Ti and Au, but may preferably be made of a metal that is conductive and that has a higher ionization tendency than hydrogen, such as chromium (Cr), nickel (Ni), aluminum (Al), a laminated film of the above-described materials and Au, or a wiring metal that is used in a general semiconductor IC. As a method of forming the wiring metal 6, the vacuum deposition method, the electron-beam evaporation method, the sputtering method, or the like may be adopted, and it is desirable that a film thickness of the wiring metal 6 is equal to or larger than 5 nm, with which an adhesive layer to the insulating film 2 is not formed in an island-shape but is likely to be formed as a continuous film, and it is desirable that a total film thickness is equal to or larger than 100 nm to reduce wiring resistance, to prevent a stepped portion from being locally thinned, and to prevent current density from being extremely increased when power is turned on.

In this manner, according to the graphene transistor of the first embodiment, it is possible to reduce the contact resistance between the graphene and the electrode, which is needed for the source electrode 4 and the drain electrode 5 that are connected to the channel 3, and improve the adhesiveness between the insulating film 2 and the electrode, which is needed for the wiring metal 6 on the insulating film 2, by separately adopting an appropriate material and an appropriate method. As a result, it is possible to reduce the contact resistance between the graphene and the electrode and improve the adhesiveness between the insulating film 2 and the electrode, which is needed for the wiring metal 6 on the insulating film 2.

### Modification 1-1

FIG. 2B is a diagram illustrating an example of a configuration of a graphene transistor according to a modification 1-1. In the present modification, the source electrode 4 and the drain electrode 5 are disposed on the channel 3 and not connected to the insulating film 2. In other words, the source electrode 4 and the drain electrode 5 are disposed on only the channel 3. With this configuration, it is possible to reduce a contact area between each of the source electrode 4 and the drain electrode 5 and the insulating film 2, so that it is possible to improve adhesiveness between the insulating film 2 and the electrodes, which is needed for the wiring metal 6 on the insulating film 2.

### Modification 1-2

FIG. 2C is a diagram illustrating an example of a configuration of a graphene transistor according to a modification 1-2. In the present modification, the wiring metal 6 completely covers the source electrode 4 and the drain electrode 5. With this configuration, it is possible to increase a contact area between the wiring metal 6 and each of the source electrode 4 and the drain electrode 5, so that it is possible to reduce contact resistant against the source electrode 4 and the drain electrode 5. Furthermore, it is possible to physically press the source electrode 4 and the drain electrode 5 from above, so that it is possible to improve adhesiveness between the insulating film 2 and the electrodes, which is needed for the wiring metal 6 on the insulating film 2.

### Modification 1-3

FIG. 2D is a diagram illustrating an example of a configuration of a graphene transistor according to a modification 1-3. In the present modification, the source electrode 4 and the drain electrode 5 are disposed on only the channel 3 and are not connected to the insulating film 2. Further, the wiring metal 6 completely covers the source electrode 4 and the drain electrode 5. With this configuration, it is possible to improve adhesiveness between the insulating film 2 and the electrodes, which is needed for the wiring metal 6 on the insulating film 2, and it is possible to reduce contact resistance between the graphene and the electrode.

### Modification 1-4

FIG. 2E is a diagram illustrating an example of a configuration of a graphene transistor according to a modification 1-4. In the present modification, the channel 3 is disposed on a part of side surfaces of the source electrode 4 and the drain electrode 5. Specifically, both ends of the channel 3 are connected to respective side surfaces of the source electrode 4 and the drain electrode 5. In this case, the channel 3 is formed after the source electrode 4 and the drain electrode 5 are formed, so that it is possible to eliminate a single step in a process after formation of the channel 3. If the channel 3 is graphene, in a processing process (for example, a photolithography process), photoresist comes into contact with the graphene and is developed, and thereafter, the resist is removed. However, if a resist residue is present on the graphene, the graphene is unintentionally doped, so that electrical property may be degraded and in-plane variation may occur. According to the present modification, it is possible to reduce the above-described risk by elimination of a single step.

### Modification 1-5

FIG. 2F is a diagram illustrating an example of a configuration of a graphene transistor according to a modification 1-5. In the present modification, both ends of the channel 3 are connected to respective top surfaces of the source electrode 4 and the drain electrode 5. Further, in the present modification, the channel 3 covers a part of the side surfaces and the top surfaces of the source electrode 4 and the drain electrode 5. An upper portion of the channel 3 on the source electrode 4 and the drain electrode 5 is connected to the wiring metal 6, so that it is possible to increase a contact area between the channel 3 and the metal and reduce the contact resistance, which is advantageous.

### Modification 1-6

FIG. 2G is a diagram illustrating an example of a configuration of a graphene transistor according to a modification 1-6. In the present modification, the source electrode 4 and the drain electrode 5 are embedded in the insulating film 2. With this configuration, the channel 3 is formed on a flatter plane, so that it is possible to ignore negative influences, such as an unintended stress to the channel 3. As compared to the graphene transistor according to the first embodiment and the graphene transistor according to the modifications 1-1 to 1-5, the plane is flatter, so that when used as a solution-gate sensor, it is possible to easily allow flow-in and flow-out of a solution and it is possible to easily form a flow path in post process, which is advantageous.

### Modification 1-7

FIG. 2H is a diagram illustrating an example of a configuration of a graphene transistor according to a modification 1-7. In the present modification, the entire graphene transistor (at least the channel 3, the source electrode 4, the drain electrode 5, and the wiring metal 6) is covered by a protection film 7. With this configuration, it is possible to prevent the channel 3, the source electrode 4, the drain electrode 5, and the wiring metal 6 from being affected by a surrounding environment, such as temperature and humidity. In particular, when the channel 3 is graphene, the channel 3 is largely affected by the surrounding environment, and therefore, by covering the channel 3 by the protection film 7, it is possible to prevent an unintended influence of the surrounding environment.

As the protection film 7, an aluminum oxide film Al₂O₃, a silicon oxide film SiOₓ, a hafnium oxide film HfOₓ, a tantalum oxide film TaOₓ, or a titanium oxide film TiOₓ, which is formed by an atomic layer deposition (ALD) method, a silicon nitride film SiNₓ or a silicon oxide film SiOₓ, which is formed by a chemical vapor deposition (CVD) method, a silicon oxide film SiOₓ, which is formed by the sputtering method, or a laminated film of the above-described films may be adopted. It is desirable to set a film thickness of the protection film 7 to equal to or larger than 50 nm to prevent, in particular, permeation of moisture or the like in the surrounding environment.

### Second Embodiment

A second embodiment is an example in which a bottom-gate graphene transistor is used as a graphene transistor. In the following description, explanation of the same components as those of the embodiment and the modifications as described above will be omitted.

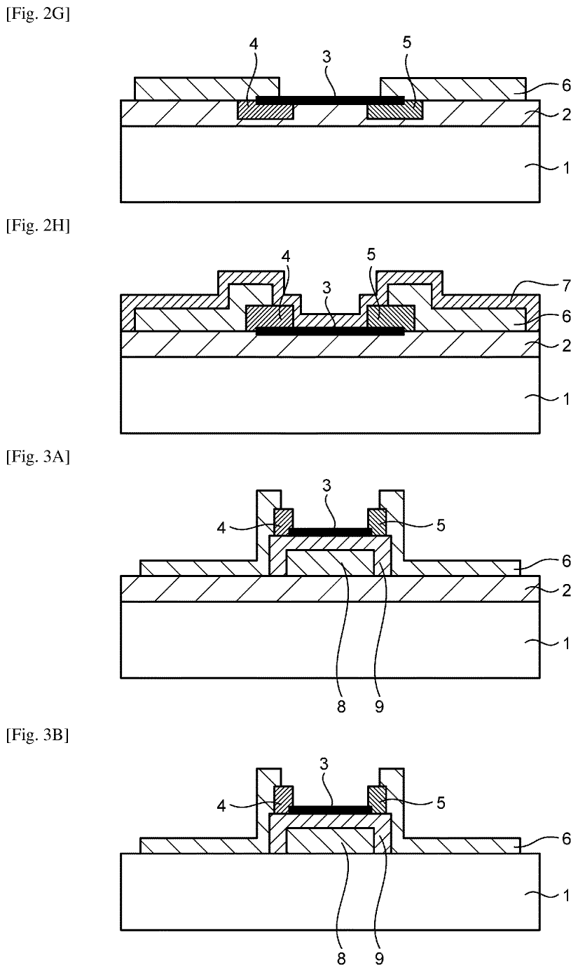

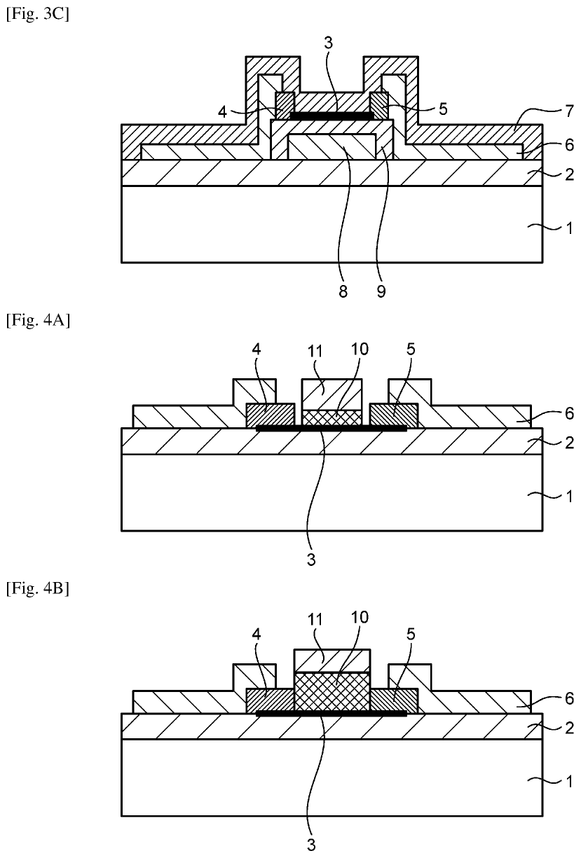

FIG. 3A is a diagram illustrating an example of a configuration of a graphene transistor according to the second embodiment. Specifically, FIG. 3A is a diagram illustrating an example of a bottom-gate graphene transistor in which a contact metal that comes into contact with the graphene channel and a wiring metal on the insulating film are separately formed. The graphene transistors illustrated in FIG. 2A to FIG. 2H are back-gate transistors that use the conductive substrate 1, such as a heavily-doped silicon substrate, and the substrate 1 is used as a gate electrode.

The graphene transistor according to the present embodiment includes, as illustrated in FIG. 3A, a gate electrode 8 that is disposed on the insulating film 2 and that functions as a bottom-gate electrode, and a gate insulating film 9 around the gate electrode 8. Further, the source electrode 4 and the drain electrode 5 are connected to the insulating film 2 and the gate insulating film 9 via the wiring metal 6.

As the gate electrode 8, similarly to the wiring metal 6, a material that has high adhesiveness to the insulating film 2 and the gate insulating film 9, such as titanium (Ti), chromium (Cr), nickel (Ni), aluminum (Al), a laminated film of the above-described materials and Au, or a wiring metal that is used in a general semiconductor IC, may be adopted. As a method of forming the gate electrode 8, the vacuum deposition method, the electron-beam evaporation method, the sputtering method, or the like may be adopted. Further, it is desirable that a film thickness of the gate electrode 8 is equal to or larger than 5 nm, with which an adhesive layer to the insulating film 2 is not formed in an island-shape but is likely to be formed as a continuous film, and it is desirable that a total film thickness is equal to or larger than 100 nm to reduce wiring resistance and equal to or smaller than 1 μm to form the gate insulating film 9 with good coverability around the gate electrode 8.

As the gate insulating film 9, an aluminum oxide film Al₂O₃, a silicon oxide film SiOₓ a hafnium oxide film HfOₓ, a tantalum oxide film TaOₓ, or a titanium oxide film TiOₓ which is formed by the ALD method, a silicon nitride film SiNₓ or a silicon oxide film SiOₓ, which is formed by the CVD method, a silicon oxide film SiOₓ, which is formed by the sputtering method, or a laminated film of the above-described films may be adopted. According to Expressions (1) and (3) as described above, it is preferable to reduce the film thickness of the gate insulating film 9 (about 5 to 100 nm) and increase relative permittivity.

In this manner, according to the graphene transistor of the second embodiment, even in the bottom-gate graphene transistor, it is possible to achieve the same functions and effects as those of the embodiment and the modifications as described above.

### Modification 2-1

FIG. 3B is a diagram illustrating an example of a configuration of a graphene transistor according to a modification 2-1. In the present modification, when the substrate 1 has insulating property, the insulating film 2 need not be disposed. In this case, the gate electrode 8 is disposed on the substrate 1, and therefore, the substrate 1 need not always be conductive, but may be a flexible substrate, such as polyethylene terephthalate (PET) or polyethylene naphthalate (PEN).

### Modification 2-2

FIG. 3C is a diagram illustrating an example of a configuration of a graphene transistor according to a modification 2-2. In the present modification, the entire graphene transistor (at least the channel 3, the source electrode 4, the drain electrode 5, the wiring metal 6, and the gate insulating film 9) is covered by the protection film 7. With this configuration, it is possible to prevent the channel 3, the source electrode 4, the drain electrode 5, the wiring metal 6, and the gate insulating film 9 from being affected by a surrounding environment, such as temperature and humidity. In particular, when the channel 3 is graphene, the channel 3 is largely affected by the surrounding environment, and therefore, by covering the channel 3 by the protection film 7, it is possible to prevent an unintended influence of the surrounding environment.

### Third Embodiment

A third embodiment is an example in which a top-gate graphene transistor is used as a graphene transistor. In the following description, explanation of the same components as those of the embodiments and the modifications as described above will be omitted.

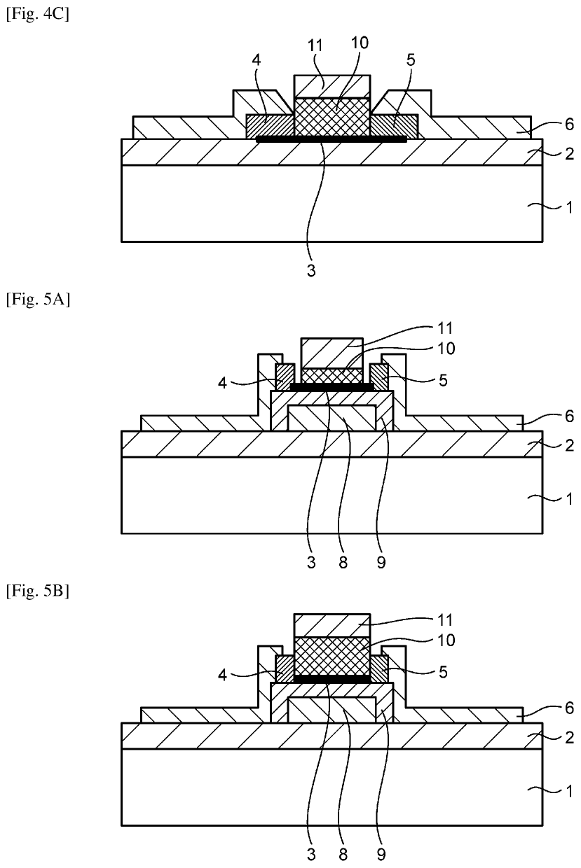

FIG. 4A is a diagram illustrating an example of a configuration of a graphene transistor according to the third embodiment. Specifically, FIG. 4A is a diagram illustrating an example of a top-gate graphene transistor in which contact metals that come into contact with the graphene channel and a wiring metal on the insulating film are separately formed. The graphene transistor according to the present embodiment includes a gate insulating film 10 that is disposed on the channel 3 and a gate electrode 11 that is disposed on the gate insulating film 10. The gate electrode 11 needs to be prevented from being connected to the source electrode 4 and the drain electrode 5. Further, the source electrode 4 and the drain electrode 5 are connected to the insulating film 2 via the wiring metal 6.

The graphene transistor according to the present embodiment includes the gate electrode 11, and therefore, the substrate 1 need not always be conductive, but may be a flexible substrate, such as polyethylene terephthalate (PET) or polyethylene naphthalate (PEN). If the graphene transistor is formed on the flexible substrate 1, it is possible to form a sensor or the like in which the graphene transistor is applied on a curved surface, so that, for example, it is possible to implement a sensor that can be attached to a human body, which is extremely useful for sensing vital data.

Furthermore, by forming the graphene transistor on the flexible substrate 1, it is possible to bring the sensor into close contact with a body, so that it is possible to accurately detect a heart rate and a myoelectric potential in real time, which may make it possible to perform sensing of body fluids, such as body odor, sweat, or tears, in real time and recognize a health condition, a feeling, and the like from data of the body fluids. Moreover, when the substrate 1 has insulating property, the insulating film 2 may be omitted.

As the gate insulating film 10, an aluminum oxide film Al₂O₃, a silicon oxide film SiOₓ, a hafnium oxide film HfOₓ, a tantalum oxide film TaOₓ, or a titanium oxide film TiOₓ, which is formed by the ALD method, a silicon nitride film SiNₓ or a silicon oxide film SiOₓ, which is formed by the CVD method, a silicon oxide film SiOₓ, which is formed by the sputtering method, or a laminated film of the above-described films may be adopted. According to Expressions (1) and (3) as described above, it is preferable to reduce the film thickness of the gate insulating film 10 (about 5 to 100 nm) and increase relative permittivity.

As the gate electrode 11, similarly to the wiring metal 6, a material that has high adhesiveness to the insulating film 2, such as titanium (Ti), chromium (Cr), nickel (Ni), aluminum (Al), a laminated film of the above-described materials and Au, or a wiring metal that is used in a general semiconductor IC, may be adopted. As a method of forming the gate electrode 11, the vacuum deposition method, the electron-beam evaporation method, the sputtering method, or the like may be adopted. It is desirable that a film thickness of the gate electrode 11 is equal to or larger than 5 nm, with which an adhesive layer to the insulating film 2 is not formed in an island-shape but is likely to be formed as a continuous film, and it is desirable that a total film thickness is equal to or larger than 100 nm to reduce wiring resistance and equal to or smaller than 1 μm to form the gate electrode 11 with good coverability around the gate insulating film 10. Furthermore, the gate electrode 11 may be formed at the same time as forming the wiring metal 6.

In this manner, according to the graphene transistor of the third embodiment, even in the top-gate graphene transistor, it is possible to achieve the same functions and effects as those of the embodiments and the modifications as described above.

### Modification 3-1

FIG. 4B is a diagram illustrating an example of a configuration of a graphene transistor according to a modification 3-1. In the present modification, as illustrated in FIG. 4B, the source electrode 4 and the drain electrode 5 are connected to the gate insulating film 10. A carrier that may be induced by gate voltage occurs in a region just below the gate electrode 11 via the gate insulating film 10, and therefore, if a distance between the region just below the gate electrode 11 and each of the source electrode 4 and the drain electrode 5 (access region) increases, a region in which the carrier is induced in the channel 3 decreases, so that a drain electrical current I_{d}, is eventually reduced. Therefore, it is desirable to reduce the access region. To cope with this, in the present modification, as illustrated in FIG. 4B, the source electrode 4 and the drain electrode 5 are connected to the gate insulating film 10 to eliminate the access region, so that it is possible to induce the carried in the entire channel 3.

### Modification 3-2

FIG. 4C is a diagram illustrating an example of a configuration of a graphene transistor according to a modification 3-2. In the present modification, as illustrated in FIG. 4C, the source electrode 4 and the drain electrode 5 are covered by the wiring metal 6, and slopes are formed in the wiring metal 6 from ends of the source electrode 4 and the drain electrode 5 opposite to the gate electrode 11 to opposite ends. With this configuration, it is possible to prevent a current short that may occur by contact between the wiring metal 6 and the gate electrode 11, and it is possible to increase a contact area between each of the source electrode 4 and the drain electrode 5 and the wiring metal 6. Furthermore, even in the graphene transistor according to the present modification (top-gate transistor), the entire graphene transistor (at least the channel 3, the source electrode 4, the drain electrode 5, the wiring metal 6, the gate insulating film 10, and the gate electrode 11) may be covered by the protection film 7.

### Fourth Embodiment

A fourth embodiment is an example in which a dual-gate transistor is used as a graphene transistor. In the following description, explanation of the same components as those of the embodiments and the modifications as described above will be omitted.

FIG. 5A is a diagram illustrating an example of a configuration of a graphene transistor according to the fourth embodiment. Specifically, FIG. 5A is a diagram illustrating a dual-gate transistor that is a graphene transistor in which the bottom-gate transistor illustrated in FIG. 3-1 and the top-gate transistor illustrated in FIG. 4A are combined, and that is able to control gate voltage at a two gates, such as a bottom gate (the gate electrode 8) and a top gate (the gate electrode 11).

The gate electrode 8 is an example of a bottom-gate electrode that is disposed on the insulating film 2. The gate insulating film 9 is an example of a bottom-gate insulating film that is disposed around the gate electrode 8. The channel 3 is disposed on the gate insulating film 9. The gate insulating film 10 is an example of a top-gate insulating film that is disposed on the channel 3. The gate electrode 11 is an example of a top-gate electrode that is disposed on the gate insulating film 10.

By providing the two gates, it is possible to adjust one of the gates at a fermi level, that is, it is possible to adjust threshold voltage (Dirac voltage when the channel 3 is graphene) to arbitrary voltage. Even in the top-gate transistors illustrated in FIG. 4A to FIG. 4C, if the substrate 1 is formed as a conductive substrate, it is possible to use two gates, such as the substrate 1 and the top gate (the gate electrode 11); however, when an array is formed, in the case of the graphene transistors illustrated in FIG. 4A and FIG. 4B, voltage applied to the substrate 1 is applied to all of transistors, so that it is difficult to apply different voltage to each of the transistors. In contrast, in the case of the graphene transistor illustrated in FIG. 5A, it is possible to apply different voltage to each of the transistors when an array is formed, so that it is possible to use one of the gate electrode 8 and the gate electrode 11 to adjust each of the transistors at a fermi level, and it is possible to correct in-plane variation or the like.

In this manner, according to the graphene transistor of the fifth embodiment, even in the dual-gate graphene transistor, it is possible to achieve the same functions and effects as those of the embodiments and the modifications as described above.

### Modification 4-1

FIG. 5B is a diagram illustrating an example of a configuration of a graphene transistor according to a modification 4-1. In the present modification, as illustrated in FIG. 5B, the source electrode 4 and the drain electrode 5 are connected to the gate insulating film 10. With this configuration, the access region is eliminated, which is desirable due to the same reason as described in the modification 3-1.

### Modification 4-2

FIG. 5C is a diagram illustrating an example of a configuration of a graphene transistor according to a modification 4-2. In the present modification, as illustrated in FIG. 5C, the source electrode 4 and the drain electrode 5 are covered by the wiring metal 6, and slopes are formed in the wiring metal 6 from ends of the source electrode 4 and the drain electrode 5 opposite to the gate electrode 11 to opposite ends. This configuration is desirable due to the same reason as described in the modification 3-3. Furthermore, even the entire top-gate transistor (at least the channel 3, the source electrode 4, the drain electrode 5, the wiring metal 6, the gate electrode 8, the gate insulating film 9, the gate insulating film 10, and the gate electrode 11) may be covered by the protection film 7.

### Fifth Embodiment

A fifth embodiment is an example in which a solution-gate graphene transistor is used as a graphene transistor. In the following description, explanation of the same components as those of the embodiments and the modifications as described above will be omitted.

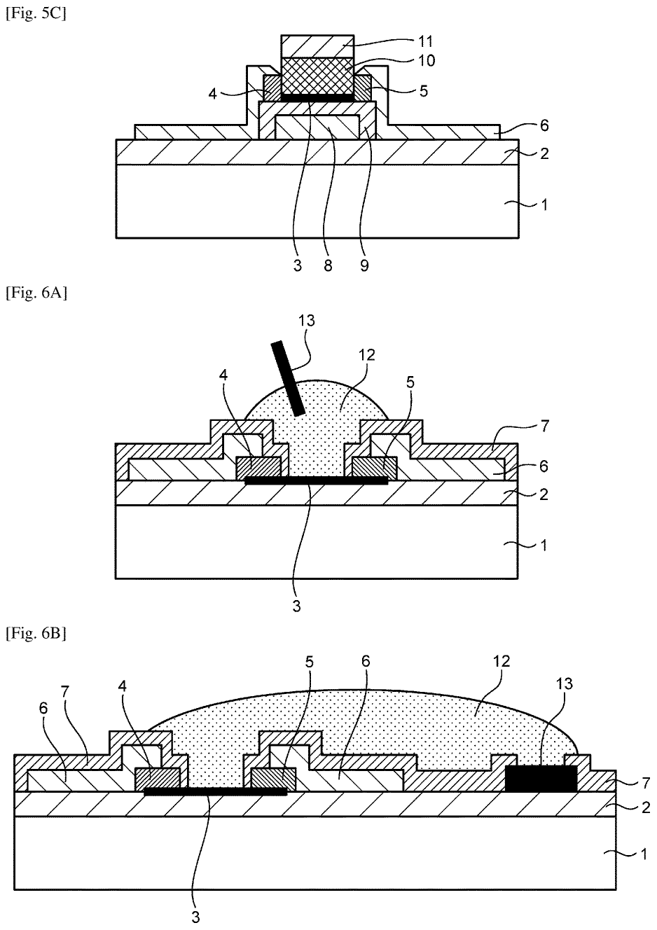

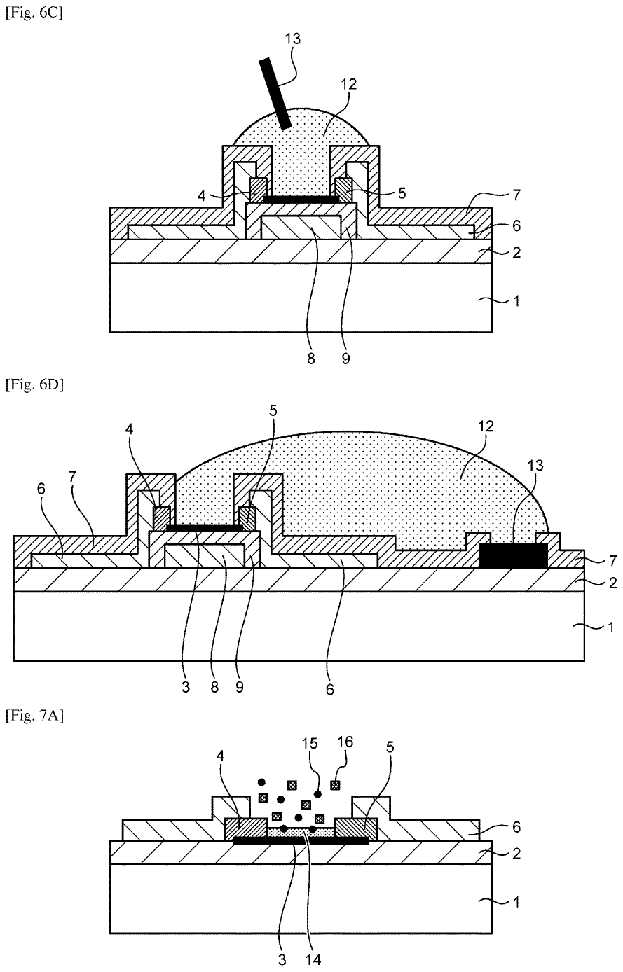

FIG. 6A is a diagram illustrating an example of a configuration of a graphene transistor according to the fifth embodiment. The graphene transistor according to the present embodiment is, as illustrated in FIG. 6A, an example of a solution-gate graphene transistor in which contact metals (the source electrode 4 and the drain electrode 5) that come into contact with a graphene channel (the channel 3) and the wiring metal 6 on the insulating film 2 are separately formed.

The graphene transistor according to the present embodiment includes a solution 12 that connects a gate electrode 13 and the channel 3 and that forms an electrical double layer on the channel 3, and the gate electrode 13 that is connected to the solution 12. Further, in the graphene transistor according to the present embodiment, an electrical double layer is formed in the vicinity of the gate electrode 13 and the channel 3 by application of voltage to the gate electrode 13, so that it is possible to induce a carrier in the channel 3 and the graphene transistor can operate as a transistor. A thickness of the electrical double layer that is formed in the vicinity of the gate electrode 13 and the channel 3 is about a several nm, so that it is possible to apply a high electric field to the channel 3 at low voltage.

The solution 12 is not specifically limited as long as the solution is a liquid that can form the electrical double layer, but Phosphate-Buffered Saline (PBS) or the like that can maintain constant pH is preferable to ensure characteristic stability of the graphene transistor. The gate electrode 13 is not specifically limited as long as the gate electrode 13 is connected to the channel 3 via the solution 12, and may be made of the same material as the source electrode 4 and the drain electrode 5 or the wiring metal 6. It is preferable to use, as the gate electrode 13, a silver-silver chloride (Ag/AgCl) electrode, a calomel electrode, a palladium/hydrogen electrode (Pd/H₂), or the like that is excellent in terms of stability and reproducibility of electrode potential in the solution 12.

In this manner, according to the graphene transistor of the fifth embodiment, even in the solution-gate graphene transistor, it is possible to achieve the same functions and effects as those of the embodiments and the modifications as described above.

### Modification 5-1

FIG. 6B is a diagram illustrating an example of a configuration of a graphene transistor according to a modification 5-1. In the graphene transistor according to the present modification, as illustrated in FIG. 6B, the gate electrode 13 is disposed at a different position from the channel 3 on the insulating film 2. With this configuration, it is possible to form the gate electrode 13 at the same time as forming the wiring metal 6, which is advantageous.

### Modification 5-2

FIG. 6C is a diagram illustrating an example of a configuration of a graphene transistor according to a modification 5-2. The graphene transistor according to the present modification includes, as illustrated in FIG. 6C, the gate electrode 8 that is an example of a bottom-gate electrode disposed on the insulating film 2, and the gate insulating film 9 that is disposed around the gate electrode 8. Further, the channel 3 is disposed on the gate insulating film 9. With this configuration, it is possible to use the graphene transistor as the dual-gate transistor, so that when an arrays is formed, it is possible to apply different voltage to each of transistors, it is possible to use one of the gate electrode 8 and the gate electrode 13 to adjust each of the transistors at a fermi level, and it is possible to correct in-plane variation or the like.

### Modification 5-3

FIG. 6D is a diagram illustrating an example of a configuration of a graphene transistor according to a modification 5-3. The graphene transistor according to the present modification is, as illustrated in FIG. 6D, a graphene transistor in which the graphene transistor according to the modification 5-1 and the graphene transistor according to the modification 5-2 are combined.

### Sixth Embodiment

A sixth embodiment is an example in which a graphene transistor is used for a gas-molecule identification sensor. In the following description, explanation of the same components as those of the embodiments and the modifications as described above will be omitted.

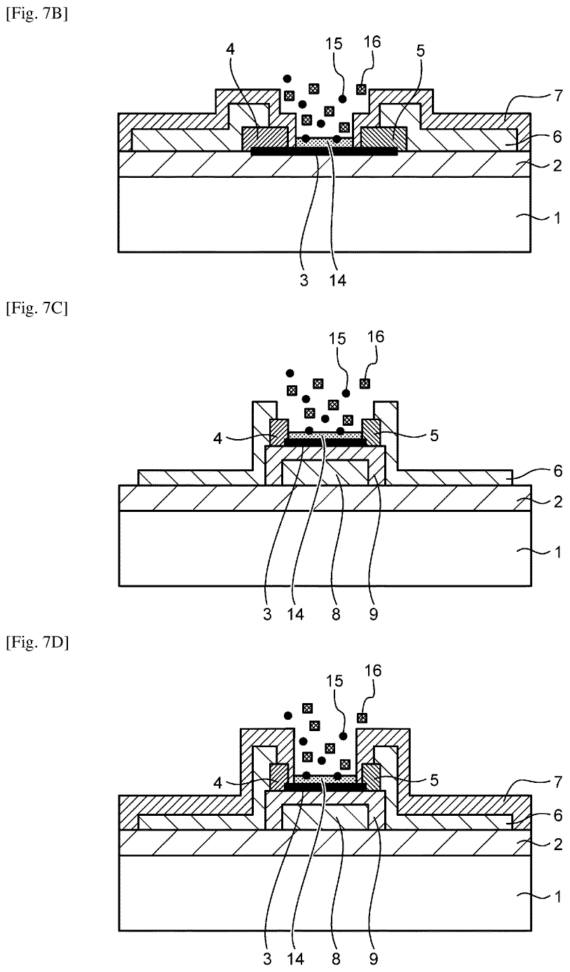

FIG. 7A is a diagram illustrating an example of a configuration of a graphene transistor according to a sixth embodiment. The graphene transistor according to the present embodiment is, as illustrated in FIG. 7A, a gas sensor in which contact metals (the source electrode 4 and the drain electrode 5) that come into contact with a graphene channel (the channel 3) disposed on the insulating film 2 and the wiring metal 6 on the insulating film 2 are separately formed, and includes a receptive layer 14 on the channel 3. The receptive layer 14 may cover the entire channel 3 or only a part of the channel 3.

The graphene transistor according to the present embodiment is able to electrically sense presence or absence of a target substance 15 and concentration of the target substance 15 by a change of the electrical current I_{ds} that flows between the source electrode 4 and the drain electrode 5 when the receptive layer 14 captures the target substance 15. The receptive layer 14 captures only the target substance 15, and does not react to substances 16 other than the target substance. For example, when the target substance 15 is hydrogen (H₂), the receptive layer 14 may be a palladium (Pd) film or the like. Further, when the target substance 15 is oxygen (O₂), the receptive layer 14 may be a titanium oxide (TiO₂) film. Furthermore, when the target substance 15 is nitrogen dioxide (NO₂), the receptive layer 14 may be a zinc oxide (ZnO) film, a tin oxide (SnO₂) film, or the like. Moreover, when the target substance 15 is ammonia (NH₃), the receptive layer 14 may be a cuprous bromide (CuBr) film or the like.

In this manner, according to the graphene transistor of the sixth embodiment, even when the graphene transistor is used as a gas-molecule identification sensor, it is possible to achieve the same functions and effects as those of the embodiments and the modifications as described above.

### Modification 6-1

FIG. 7B is a diagram illustrating an example of a configuration of a graphene transistor according to a modification 6-1. In the graphene transistor according to the present modification, as illustrated in FIG. 7B, the entire surface (at least the source electrode 4, the drain electrode 5, and the wiring metal 6) of the graphene transistor except for the receptive layer 14 is covered by the protection film 7. By covering the surface of the graphene transistor by the protection film 7, it is possible to protect the source electrode 4, the drain electrode 5, and the wiring metal 6 from the surrounding environment or the like.

### Modification 6-2

FIG. 7C is a diagram illustrating an example of a configuration of a graphene transistor according to a modification 6-2. The graphene transistor according to the present modification includes, as illustrated in FIG. 7C, the gate electrode 8 that is disposed on the insulating film 2 and the gate insulating film 9 that is disposed around the gate electrode 8. Further, the channel 3 is disposed on the gate insulating film 9. In the graphene transistor illustrated in FIG. 7A, the substrate 1 serves as a gate electrode; however, the gate electrode is present on a back surface of the substrate 1 and therefore mounting or the like is restricted. In contrast, in the graphene transistor according to the present modification, as illustrated in FIG. 7C, all of the gate electrode 8, the source electrode 4, and the drain electrode 5 are present on the surface of the graphene transistor, so that it is possible to increase a degree of freedom of mounting, a layout of element arrangement, or the like.

### Modification 6-3

FIG. 7D is a diagram illustrating an example of a configuration of a graphene transistor according to a modification 6-3. The graphene transistor according to the present modification is, as illustrated in FIG. 7D, a graphene transistor in which the graphene transistor illustrated in FIG. 7B and the graphene transistor illustrated in FIG. 7C are combined. With this configuration, it is possible to realize protection from the surrounding environment or the like and improve a degree of freedom of mounting, a layout of element arrangement, or the like.

### Seventh Embodiment

A seventh embodiment is an example in which a graphene transistor is used as a solution-gate molecular identification sensor. In the following description, explanation of the same components as those of the embodiments and the modifications as described above will be omitted.

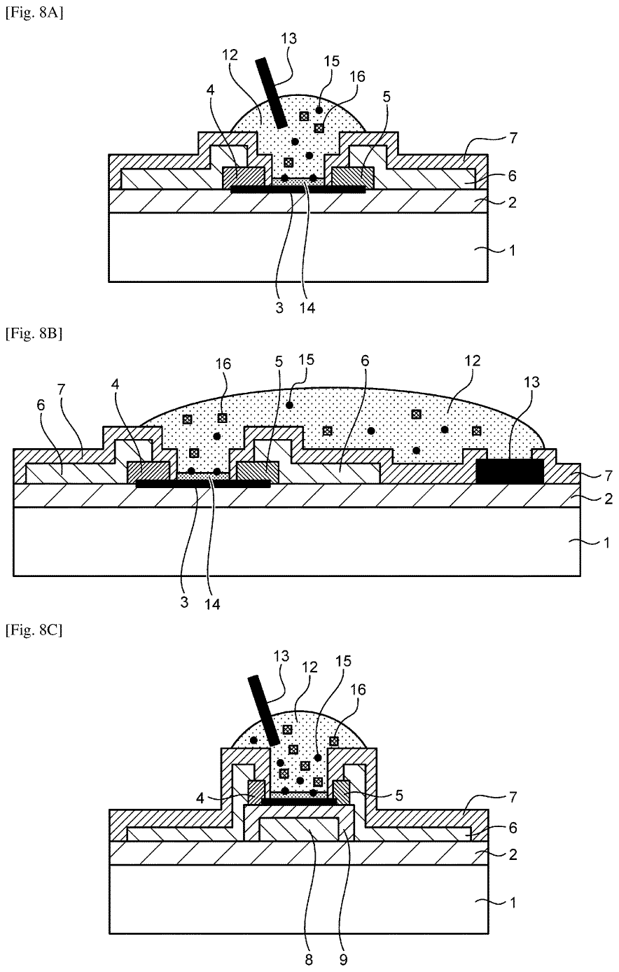

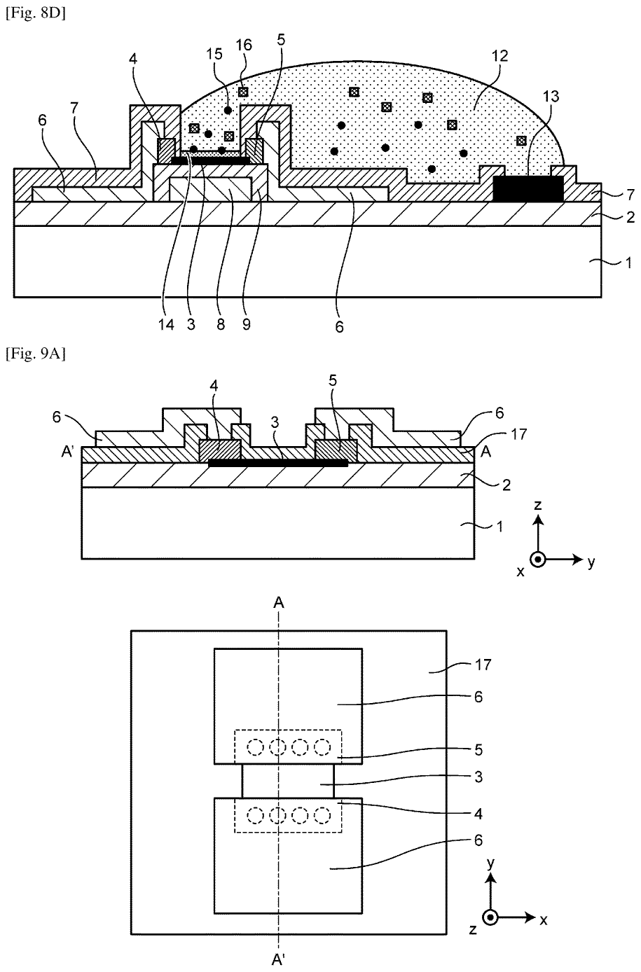

FIG. 8A is a diagram illustrating an example of a configuration of a graphene transistor according to the seventh embodiment. The graphene transistor according to the present embodiment is a solution-gate molecular identification sensor in which contact metals (the source electrode 4 and the drain electrode 5) that come into contact with a graphene channel (the channel 3) and the wiring metal 6 on the insulating film 2 are separately formed. Further, the graphene transistor according to the present embodiment includes the receptive layer 14 on the channel 3, the solution 12 that connects the gate electrode 13 and the receptive layer 14 and that forms an electrical double layer the receptive layer 14, and the gate electrode 13 that is connected to the solution 12.

The receptive layer 14 may cover the entire channel 3 or only a part of the channel 3. The graphene transistor according to the present embodiment is able to electrically sense presence or absence of the target substance 15 and a concentration of the target substance 15 by a change of the electrical current I_{d}, that flows between the source electrode 4 and the drain electrode 5 when the receptive layer 14 captures the target substance 15.

The receptive layer 14 captures only the target substance 15, and does not react to the substances 16 other than the target substance. The receptive layer 14 is appropriately selected depending on the target substance 15. For example, the target substance 15 is a molecule, it is preferable that the receptive layer 14 is a corresponding molecular template or a nucleic acid aptamer (DNA, RNA). Further, when the target substance 15 is ion, it is preferable that the receptive layer 14 is a corresponding ionophore. Furthermore, when the target substance 15 is an antigen, such as hormone, it is preferable that the receptive layer 14 is a corresponding antibody or a nucleic acid aptamer (DNA, RNA). Moreover, when the target substance 15 is a nucleic acid molecule, it is preferable that the receptive layer 14 is a corresponding nucleic acid (DNA, RNA). Furthermore, when the target substance 15 is amino acid, protein, and the like, it is preferable that the receptive layer 14 is a corresponding peptide aptamer or a nucleic acid aptamer (DNA, RNA).

For example, when a hormone balance is to be sensed from saliva, blood, urine, tears, sweat, or the like, the target substance 15 may be estrone, estradiol, estriol, progesterone, testosterone, dihydrotestosterone (DHT), androstenedione, androsterone, cortisol (hydrocortisone), serotonin, dopamine, oxytocin, adrenaline, norepinephrine, melatonin, erythropoietin, or the like, and by sensing the hormone as described above by the graphene transistor, it is possible to visualize a stress, happiness, or the like.

The substrate 1 need not always be conductive, but may be a flexible substrate, such as polyethylene terephthalate (PET) or polyethylene naphthalate (PEN). If the graphene transistor is formed on the flexible substrate 1, it is possible to form a sensor or the like in which the graphene transistor is applied on a curved surface, so that, for example, it is possible to implement a sensor or the like that can be attached to a human body, which is extremely useful for sensing vital data. Furthermore, by forming the graphene transistor on the flexible substrate 1, it is possible to bring the sensor into close contact with a body, so that it is possible to accurately detect a heart rate and a myoelectric potential in real time, which may make it possible to perform sensing of body fluids, such as body odor, sweat, or tears, in real time and recognize a health condition, a feeling, and the like from data of the body fluids. When the substrate 1 has insulating property, the insulating film 2 may be omitted.

In this manner, according to the graphene transistor of the seventh embodiment, even when the graphene transistor is used as a solution-gate molecular identification sensor, it is possible to achieve the same functions and effects as those of the embodiments and the modifications as described above.

### Modification 7-1

FIG. 8B is a diagram illustrating an example of a configuration of a graphene transistor according to a modification 7-1. In the graphene transistor according to the present modification, as illustrated in FIG. 8B, the gate electrode 13 is disposed at a different position from the channel 3 on the insulating film 2. With this configuration, it is possible to form the gate electrode 13 at the same time as forming the wiring metal 6, which is advantageous.

### Modification 7-2

FIG. 8C is a diagram illustrating an example of a configuration of a graphene transistor according to a modification 7-2. The graphene transistor according to the present modification includes, as illustrated in FIG. 8C, the gate electrode 8 that is an example of a bottom-gate electrode disposed on the insulating film 2, and the gate insulating film 9 that is disposed around the gate electrode 8. Further, the channel 3 is disposed on the gate insulating film 9. With this configuration, similarly to the fourth embodiment, it is possible to use the graphene transistor as the dual-gate transistor, so that when an arrays is formed, it is possible to apply different voltage to each of transistors, it is possible to use one of the gate electrode 8 and the gate electrode 11 to adjust each of the transistors at a fermi level, and it is possible to correct in-plane variation or the like.

### Modification 7-3

FIG. 8D is a diagram illustrating an example of a configuration of a graphene transistor according to a modification 7-3. The graphene transistor according to the present modification is, as illustrated in FIG. 8D, a graphene transistor in which the graphene transistor according to the modification 7-1 and the graphene transistor according to the modification 7-2 are combined.

### Eighth Embodiment

An eighth embodiments is an example in which a source electrode, a drain electrode, and a channel are covered by an interlaminar insulating film, and the source electrode and the drain electrode are connected to a wiring metal via contact holes that are included in the interlaminar insulating film. In the following description, explanation of the same components as those of the embodiments and the modifications as described above will be omitted.

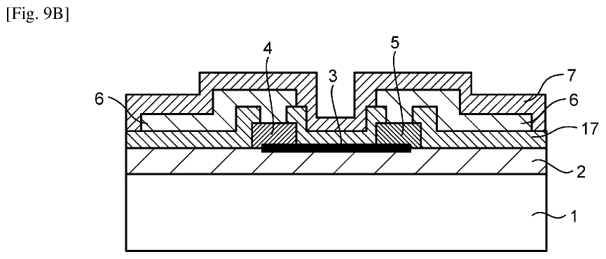

FIG. 9A is a diagram illustrating an example of a configuration of a graphene transistor according to the eighth embodiment. In the graphene transistor according to the present embodiment, as illustrated in FIG. 9A, contact metals (the source electrode 4 and the drain electrode 5) that come into contact with a graphene channel (the channel 3) and the wiring metal 6 on the insulating film 2 are separately formed. In the present embodiment, the source electrode 4, the drain electrode 5, and the channel 3 are covered by an interlaminar insulating film 17. Further, in the present embodiment, the source electrode 4 and the drain electrode 5 are connected to the wiring metal 6 via the contact holes that are included in the interlaminar insulating film 17.

In the graphene transistor according to the present embodiment, the source electrode 4 and the drain electrode 5 are first formed, the interlaminar insulating film 17 is subsequently formed, the contact holes are thereafter formed by processing, such as etching, on contact regions that come into contact with the source electrode 4 and the drain electrode 5, and the wiring metal 6 is finally formed. The number of the contact holes may be one or plural in a region that does not exceed top surface of the source electrode 4 and the drain electrode 5.

In this manner, according to the graphene transistor of the eighth embodiment, the channel 3 is covered by the interlaminar insulating film 17 at the time of forming the wiring metal 6, so that it is possible to protect the channel 3 from degradation (contact with a photoresist or the like) in a process.

### Modification 8-1

FIG. 9B is a diagram illustrating an example of a configuration of a graphene transistor according to a modification 8-1. In the graphene transistor according to the present modification, as illustrated in FIG. 9B, the entire graphene transistor (at least the interlaminar insulating film 17 and the wiring metal 6) is covered by the protection film 7. With this configuration, it is possible to prevent the wiring metal 6 from being affected by a surrounding environment, such as temperature and humidity.

An example of an experimental result about electrical property between the graphene and the electrode and the adhesiveness between the insulating film 2 and the electrode in the graphene transistors according to the embodiments and the modifications as described above will be described below.

In the experiment, graphene was transferred to a silicon substrate including a thermal oxide film with a thickness of 90 nm, patterning was performed on the graphene by a photolithography process, the graphene in an unneeded region was removed by an O2 plasma cleaner, and the resist was subjected to wet peeling-off by acetone.

A metal pattern was formed by a lift-off process. Each of metal films is formed at a following rate by electron beam deposition.

Ti: 1.0 angstrom/s, Cr: 3.0 angstroms/s, Ni: 1.0 angstroms/s, Al: 5.0 angstroms/s, Au: 3.0 angstroms/s, Pd: 3.0 angstroms/s, Ag: 1.0 angstrom/s, Pt: 1.0 angstrom/s

Further thicknesses of various kinds of metal films in the first layer were aimed at 20 nm, a thickness of Au in the second layer was aimed at 100 nm, and in the case of Au, a total thickness was aimed at 120 nm.

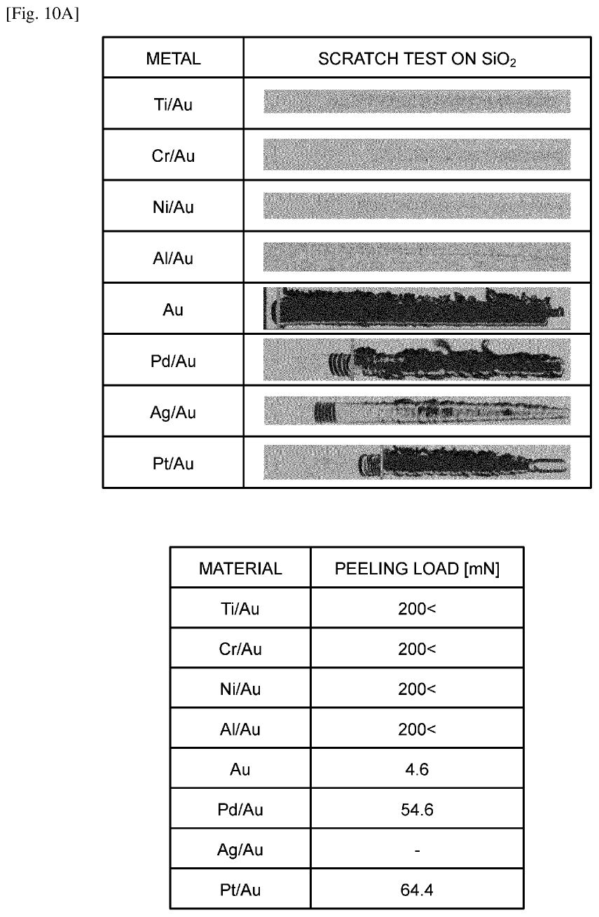

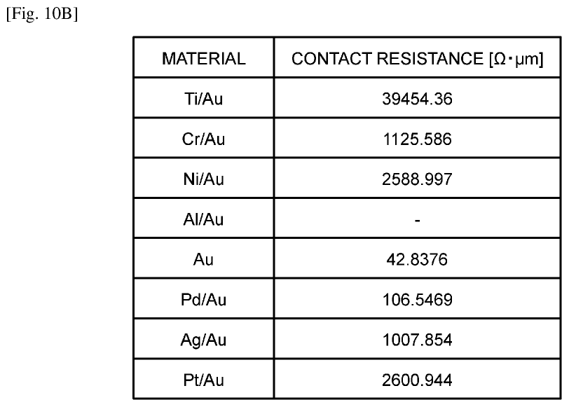

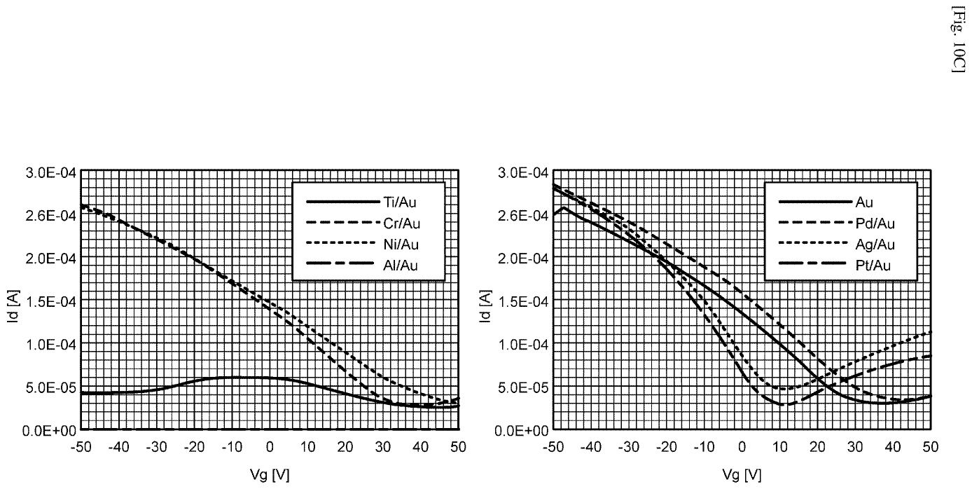

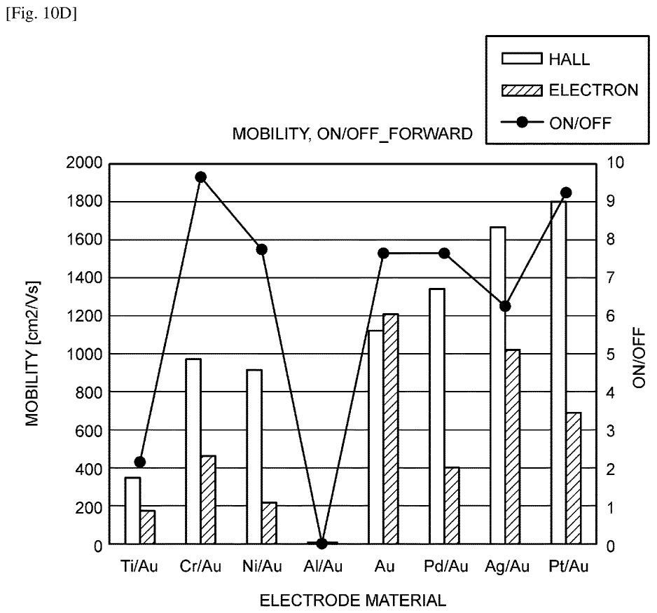

FIG. 10A illustrates a scratch test result of various kinds of metals on a silicon thermal oxide film (SiO₂). A measurement condition is determined as follows: excitation amplitude: 50 μm, excitation frequency: 45 Hz, scratch speed: 10 μm/s, initial load: 0 mN, maximum load: 200 mN, measurement time: 60 s, and a stylus diameter: 50 μm. As for the film thicknesses, the first layer has a thickness of 20 nm, the second layer (Au) has a thickness of 100 nm, and a film made of only Au has a thickness of 120 nm. It is indicated that adhesiveness increases with an increase in a peeling load. It can be found that, from the experimental result, Ti/Au, Cr/Au, Ni/Au, and Al/Au are excellent from the viewpoint of adhesiveness.

FIG. 10B illustrates a result of measurement of contact resistance between graphene and various kinds of metals by a Transfer Line Method (TLM). It is indicated that electrical property increases with a decrease in the contact resistance. It can be found that, from the experimental result, Au and Pd/Au are excellent from the viewpoint of the contact resistance. With regard to a configuration of Al/Au, resistance and variation were too high to perform measurement.

FIG. 10C is a diagram illustrating a representative example of electrical property when the source electrode and the drain electrode are made of various kinds of metals in the conventional graphene transistor illustrated in FIG. 1. In FIG. 10C, a vertical axis represents a drain electrical current (Id) and a horizontal axis represents gate voltage (Vg). FIG. 10D is a diagram illustrating average values of Hall field-effect mobility, electron field-effect mobility, ON/OFF (maximum value of a drain electrical current/minimum value of the drain electrical current) of six elements in the conventional graphene transistor illustrated in FIG. 1. In FIG. 10D, a first axis (left side) of vertical axes represents the Hall or electron mobility, a second axis (right side) of the vertical axes represents ON/OFF, and a horizontal axis represents an electrode material. The graphene transistor is more excellent with an increase in all of the Hall field-effect mobility, the electron field-effect mobility, and ON/OFF. From the experimental result, it can be found that Au, Pd, Ag, and Pt are preferable in terms of the electrical property.

From the viewpoint of adhesiveness, Ti, Ni, Cr, and Al are preferable as illustrated in FIG. 10A, but, from the viewpoint of electrical properties, Au, Pd, Ag, and Pt are preferable as illustrated in FIG. 10B to FIG. 10D. Thus, there is no metal that can realize both of adhesiveness and electrical property, with regard to the source electrode 4 and the drain electrode 5. Therefore, by separately forming the metal that is connected to the channel 3 that is effective to the electrical property and the metal on the insulating film 2 that needs to be adhesive, it is possible to realize both of the adhesiveness and the electrical property.

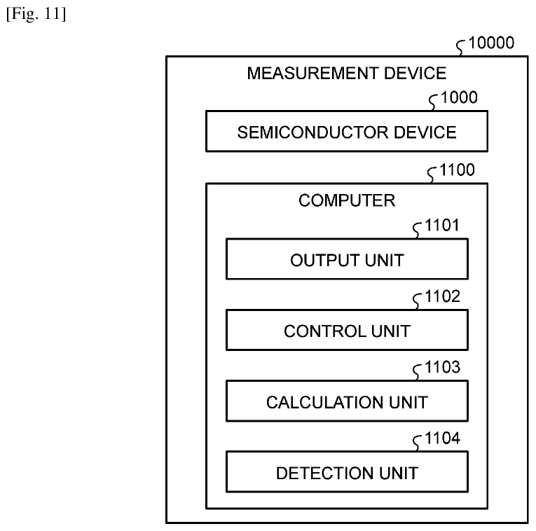

A measurement device 10000 will be described below with reference to FIG. 11. FIG. 11 is a block diagram for explaining an embodiment of the measurement device 10000. The measurement device 10000 includes the semiconductor device according to the present embodiment and a computer 1100. The computer 1100 includes an output unit 1101, a control unit 1102, a calculation unit 1103, and a detection unit 1104. The control unit 1102 controls a timing at which voltage is applied to a semiconductor device 1000, a value of voltage to be applied, or the like. The calculation unit 1103 calculates a concentration of a substance from, for example, a signal that is output by the semiconductor device 1000, and stores the calculated concentration. The output unit 1101 performs data communication with a display unit (not illustrated), and transmits a calculation result obtained by the calculation unit 1103 to the display unit.

Embodiments of the present invention are, for example, as follows.
<1> A semiconductor device including:
a gate electrode;
an insulating portion on one surface of the gate electrode;
a channel material on a surface of the insulating portion opposite to the gate electrode, the channel material including an atomic-layered material including graphene;
a source electrode connected to one end of the channel material; and
a drain electrode connected to one end of the channel material opposite to the source electrode, wherein
at least one of the source electrode and the drain electrode includes a metal material having a lower ionization tendency than hydrogen, and
at least one of the source electrode and the drain electrode is connected to the insulating portion via a metal material having a higher ionization tendency than hydrogen.
<2> The semiconductor device according to <1>, wherein the source electrode and the drain electrode are disposed on only the channel material.
<3> The semiconductor device according to <1> or <2>, wherein the metal material covers the source electrode and the drain electrode.
<4> The semiconductor device according to <1>, wherein both ends of the channel material are connected to side surfaces of the source electrode and the drain electrode, when the source electrode and the drain electrode have undersurfaces facing the insulating portion.
<5> The semiconductor device according to <1> or <4>, wherein both ends of the channel material are connected to top surfaces of the source electrode and the drain electrode, when the source electrode and the drain electrode have undersurfaces facing the insulating portion.
<6> The semiconductor device according to any one of <1> to <3>, wherein the source electrode and the drain electrode are embedded in the insulating portion.
<7> The semiconductor device according to any one of <1> to <6>, wherein the channel material, the source electrode, the drain electrode, and the metal material are covered by a protection film.
<8> A semiconductor device including:
an insulating portion;
a bottom-gate electrode on an insulating portion;
a gate insulating portion on the bottom-gate electrode;
a channel material on the gate insulating portion, the channel material including an atomic-layered material including graphene;
a source electrode connected to one end of the channel material; and
a drain electrode connected to one end of the channel material opposite to the source electrode, wherein
at least one of the source electrode and the drain electrode includes a metal material having a lower ionization tendency than hydrogen, and
at least one of the source electrode and the drain electrode is connected to the insulating portion and the gate insulating portion via a metal material having a higher ionization tendency than hydrogen.
<9> The semiconductor device according to <8>, wherein the insulating portion includes a substrate having insulating property.
<10> The semiconductor device according to <8> or <9>, wherein the bottom-gate electrode, the insulating portion, the channel material, the source electrode, the drain electrode, the metal material, and the gate insulating portion are covered by a protection film.
<11> A semiconductor device including:
an insulating portion;
a channel material on the insulating portion, the channel material including an atomic-layered material including graphene;
a gate insulating portion on the channel material;
a gate electrode on the gate insulating portion;
a source electrode connected to one end of the channel material; and
a drain electrode connected to one end of the channel material opposite to the source electrode, wherein
at least one of the source electrode and the drain electrode includes a metal material having a lower ionization tendency than hydrogen, and
at least one of the source electrode and the drain electrode is connected to the insulating portion via a metal material having a higher ionization tendency than hydrogen.
<12> The semiconductor device according to <11>, wherein the source electrode and the drain electrode are connected to the gate insulating portion.
<13> The semiconductor device according to <12>, wherein the source electrode and the drain electrode are covered by the metal material.
<14> A semiconductor device including:
an insulating portion;
a bottom-gate electrode on the insulating portion;
a bottom-gate insulating portion on the bottom-gate electrode;
a channel material on the bottom-gate insulating portion, the channel material including an atomic-layered material including graphene;
a top-gate insulating portion on the channel material;
a top-gate electrode on the top-gate insulating portion;
a source electrode connected to one end of the channel material; and
a drain electrode connected to one end of the channel material opposite to the source electrode, wherein
at least one of the source electrode and the drain electrode includes a metal material having a lower ionization tendency than hydrogen, and
at least one of the source electrode and the drain electrode is connected to the insulating portion and the bottom-gate insulating portion via a metal material having a higher ionization tendency than hydrogen.
<15> The semiconductor device according to <14>, wherein the source electrode and the drain electrode are connected to the top-gate insulating portion.
<16> The semiconductor device according to <15>, wherein the source electrode and the drain electrode are covered by the metal material.
<17> A semiconductor device including:
a gate electrode;
an insulating portion;
a channel material on the insulating portion, the channel material including an atomic-layered material including graphene;
a solution connecting the gate electrode and the channel material and forming an electrical double layer on the channel material;
a source electrode connected to one end of the channel material; and
a drain electrode connected to one end of the channel material opposite to the source electrode, wherein
at least one of the source electrode and the drain electrode includes a metal material having a lower ionization tendency than hydrogen, and
at least one of the source electrode and the drain electrode is connected to the insulating portion via a metal material having a higher ionization tendency than hydrogen.
<18> The semiconductor device according to <17>, wherein the gate electrode is disposed on the insulating portion and at a different position from the channel material.
<19> The semiconductor device according to <17> or <18>, further including:
a bottom-gate electrode on the insulating portion; and
a gate insulating portion on the bottom-gate electrode, wherein the channel material is disposed on the gate insulating portion.
<20> A semiconductor device including:
an insulating portion;
a channel material on the insulating portion, the channel material including an atomic-layered material including graphene;
a receptive layer on the channel material;
a source electrode connected to one end of the channel material; and
a drain electrode connected to one end of the channel material opposite to the source electrode, wherein
at least one of the source electrode and the drain electrode includes a metal material having a lower ionization tendency than hydrogen, and
at least one of the source electrode and the drain electrode is connected to the insulating portion via a metal material having a higher ionization tendency than hydrogen.
<21> The semiconductor device according to <20>, wherein the source electrode, the drain electrode, and the metal material are covered by a protection film.
<22> The semiconductor device according to <20> or <21>, further including:
a gate electrode on the insulating portion; and
a gate insulating portion on the gate electrode, wherein
the channel material is disposed on the gate insulating portion.
<23> A semiconductor device including:
a gate electrode;
an insulating portion;
a channel material on the insulating portion, the channel material including an atomic-layered material including graphene;
a receptive layer on the channel material;
a solution connecting the gate electrode and the receptive layer and forming an electrical double layer on the channel material;
a source electrode connected to one end of the channel material; and
a drain electrode connected to one end of the channel material opposite to the source electrode, wherein
at least one of the source electrode and the drain electrode includes a metal material having a lower ionization tendency than hydrogen, and
at least one of the source electrode and the drain electrode is connected to the insulating portion via a metal material having a higher ionization tendency than hydrogen.
<24> The semiconductor device according to <23>, wherein the gate electrode is disposed on the insulating portion and at a different position from the channel material.
<25> The semiconductor device according to <23> or <24>, further including:
a bottom-gate electrode on the insulating portion; and
a gate insulating film on the bottom-gate electrode, wherein
the channel material is disposed on the gate insulating film.
<26> A semiconductor device including:
a gate electrode;
an insulating portion on one surface of the gate electrode;
a channel material on a surface of the insulating portion opposite to the gate electrode, the channel material including an atomic-layered material including graphene;
a source electrode connected to one end of the channel material; and
a drain electrode connected to one end of the channel material opposite to the source electrode, wherein
the source electrode and the drain electrode include metal materials having lower ionization tendencies than hydrogen,
the source electrode, the drain electrode, and the channel material are covered by the interlaminar insulating film, and
at least one of the source electrode and the drain electrode is connected to a metal material having a higher ionization tendency than hydrogen via a contact hole included in the interlaminar insulating film.
<27> The semiconductor device according to <26>, wherein the interlaminar insulating film and the metal material are covered by a protection film.

### REFERENCE SIGNS LIST

1 Substrate
2 Insulating film
3 Channel
4 Source electrode
5 Drain electrode
6 Wiring metal
7 Protection film
8, 11, 13 Gate electrode
9, 10 Gate insulating film
12 Solution
14 Receptive layer
17 Interlaminar insulating film

### CITATION LIST

### Patent Literature

PTL 1: Japanese Unexamined Patent Application Publication No. 2018-014360
PTL 2: Japanese Unexamined Patent Application Publication No. 2016-127238

### Non Patent Literature

NPL 1: Seung Min Song et al., “Determination of Work Function of Graphene under a Metal Electrode and Its Rolein Contact Resistance”, Nano Lett. 2012, 12, 8, 3887-3892
NPL 2: A. Gahoi et al., “Contact resistance study of various metal electrodes with CVD graphene”, Solid-State Electronics 125 (2016) 234-239

1. A semiconductor device comprising:
an insulating portion;
a channel material on a surface of the insulating portion, the channel material including an atomic-layered material including graphene;
a source electrode connected to one end of the channel material; and
a drain electrode connected to one end of the channel material opposite to the source electrode, wherein
at least one of the source electrode and the drain electrode comprises a metal material having a lower ionization tendency than hydrogen, and
at least one of the source electrode and the drain electrode is connected to the insulating portion via a metal material having a higher ionization tendency than hydrogen.

2. The semiconductor device according to claim 1, wherein the source electrode and the drain electrode are disposed on only the channel material.

3. The semiconductor device according to claim 1, wherein the metal material covers the source electrode and the drain electrode.

4. The semiconductor device according to claim 1, wherein both ends of the channel material are connected to side surfaces of the source electrode and the drain electrode, when the source electrode and the drain electrode have undersurfaces facing the insulating portion.

5. The semiconductor device according to claim 1, wherein both ends of the channel material are connected to top surfaces of the source electrode and the drain electrode, when the source electrode and the drain electrode have undersurfaces facing the insulating portion.

6. The semiconductor device according to claim 1, wherein widths of the source electrode and the drain electrode in a direction in which the source electrode and the drain electrode are laminated on the channel material are larger than widths by which the source electrode and the drain electrode protrude from the insulating portion.

7. The semiconductor device according to claim 1, wherein the channel material, the source electrode, and the drain electrode are covered by a protection film.

8. A semiconductor device comprising:
an insulating portion;
a bottom-gate electrode on an insulating portion;
a gate insulating portion on the bottom-gate electrode;
a channel material on the gate insulating portion, the channel material including an atomic-layered material including graphene;
a source electrode connected to one end of the channel material; and
a drain electrode connected to one end of the channel material opposite to the source electrode, wherein
at least one of the source electrode and the drain electrode comprises a metal material having a lower ionization tendency than hydrogen, and
at least one of the source electrode and the drain electrode is connected to the insulating portion and the gate insulating portion via a metal material having a higher ionization tendency than hydrogen.

9.-10. (canceled)

11. A semiconductor device comprising:
an insulating portion:
a channel material on the insulating portion, the channel material including an atomic-layered material including graphene;
a gate insulating portion on the channel material;
a gate electrode on the gate insulating portion;
a source electrode connected to one end of the channel material; and
a drain electrode connected to one end of the channel material opposite to the source electrode, wherein
at least one of the source electrode and the drain electrode comprises a metal material having a lower ionization tendency than hydrogen, and
at least one of the source electrode and the drain electrode is connected to the insulating portion via a metal material having a higher ionization tendency than hydrogen.

12. The semiconductor device according to claim 11, wherein the source electrode and the drain electrode are connected to the gate insulating portion.

13. (canceled)

14. The semiconductor device according to claim 1, further comprising:
a bottom-gate electrode between the insulating portion and the channel material;
a bottom-gate insulating portion between the bottom-gate electrode and the channel material;
a top-gate electrode on a surface of the channel material opposite to a surface on which the bottom-gate insulating portion is disposed; and
a top-gate insulating portion between the channel material and the top-gate electrode.

15.-17. (canceled)

18. The semiconductor device according to claim 1, further comprising a gate electrode, wherein the gate electrode is disposed on the insulating portion and at a different position from the channel material.

19. The semiconductor device according to claim 11, further including:
a bottom-gate electrode on the insulating portion; and
a gate insulating portion on the bottom-gate electrode, wherein
the channel material is disposed on the gate insulating portion.

20. The semiconductor device according to claim 1, further comprising:
a receptive layer on a surface of the channel material opposite to a surface on which the insulating portion is disposed.

21.-25. (canceled)

26. The semiconductor device according to claim 1,
the source electrode, the drain electrode, and the channel material are covered by an interlaminar insulating film, and
the source electrode or the drain electrode is connected to a metal material having a higher ionization tendency than hydrogen via a contact hole included in the interlaminar insulating film.

27. The semiconductor device according to claim 26, wherein the interlaminar insulating film and the metal material are covered by a protection film.

28. A measurement device comprising the semiconductor device according to claim 1.

29. The semiconductor device according to claim 1, further comprising a gate electrode, wherein
the gate electrode is disposed on a surface of the insulating portion opposite to the surface on which the channel material is disposed.
